(19) United States
(12) Patent Application Publication
(10) Pub. No.: US 2023/0032354 A1
(43) Pub. Date: Feb. 2, 2023

(54) METHOD FOR FORMING PHOTORESIST PATTERNS

(71) Applicants: SAMSUNG SDI CO., LTD., Yongin-si (KR); SAMSUNG ELECTRONICS CO., LTD., Suwon-si (KR)

(72) Inventors: Ran NAMGUNG, Suwon-si (KR); Minsoo KIM, Suwon-si (KR); Hyeon PARK, Suwon-si (KR); Daeseok SONG, Suwon-si (KR); Minki CHON, Suwon-si (KR); Jun Soo KIM, Hwaseong-si (KR); Hyun-Woo KIM, Seongnam-si (KR); Hyun-Ji SONG, Anyang-si (KR); Young Joo CHOI, Hwaseong-si (KR); Suk-Koo HONG, Hwaseong-si (KR)

(21) Appl. No.: 17/847,794

(22) Filed: Jun. 23, 2022

(30) Foreign Application Priority Data
Jul. 1, 2021 (KR) 10-2021-0086511

(51) Int. Cl. G03F 7/11; C08F 20/28; C09D 133/16; H01L 21/027

(52) U.S. Cl. CPC G03F 7/11; C08F 20/28; C09D 133/16; H01L 21/0274

(57) ABSTRACT

A method for forming photoresist patterns and a semiconductor device on which a photoresist pattern manufactured according to the method is formed are disclosed. The method includes forming a preliminary photoresist pattern on a substrate; coating an organic topcoat composition including an acrylic polymer, the acrylic polymer including a structural unit containing a hydroxy group and a fluorine, and an acid compound on the preliminary photoresist pattern; drying and heating the substrate on which the organic topcoat composition is coated to coat it with a topcoat; and spraying a rinse solution including an acetate-based compound on the substrate coated with the topcoat to remove the topcoat.

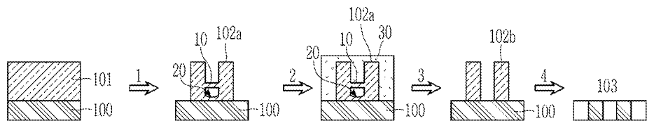

### CROSS-REFERENCE TO RELATED APPLICATION

This application claims priority to and the benefit of Korean Patent Application No. 10-2021-0086511, filed in the Korean Intellectual Property Office on Jul. 1, 2021, the entire content of which is incorporated herein by reference.

### BACKGROUND

### 1. Field

One or more embodiments of the present disclosure relate to a method for forming photoresist patterns, specifically, to a pattern processing method using a pattern treatment composition.

### 2. Description of the Related Art

Recently, the semiconductor industry has developed an ultrafine patterning technique that helps obtain a pattern in the nanometer scale (e.g., a pattern of several to several tens nanometers in sizes). Such ultrafine technique should need effective lithographic techniques.

An example lithographic technique involves forming a material layer on a semiconductor substrate, coating a photoresist layer thereon, exposing and developing to form a photoresist pattern, and then etching the material layer using the photoresist pattern as a mask.

As lithographic techniques develop, a degree of pattern integration is increasing, and materials and technologies for solving various problems occurring in this process are required (or desired). In particular, when photoresist is patterned using extreme ultraviolet (EUV) as a light source, a high-resolution pattern may be realized, but single line open (SLO) defects may occur randomly on the pattern due to photon shot noise. These SLO defects may lower yield, and thus technology development is required (or desired) to improve it.

### SUMMARY

One or more aspects of embodiments of the present disclosure are directed toward a method for forming photoresist patterns capable of not only realizing high-resolution patterns, but also removing single line open (SLO) defects to improve yield.

One or more aspects of embodiments of the present disclosure are further directed toward a semiconductor device manufactured by the method for forming photoresist patterns.

According to one or more embodiments, a method for forming photoresist patterns includes forming a photoresist pattern (e.g., a preliminary photoresist pattern) on a substrate; coating an organic topcoat composition including an acrylic polymer, the acrylic polymer including a structural unit containing a hydroxy group and a fluorine, and an acid compound on the preliminary photoresist pattern; drying and heating the substrate on which the organic topcoat composition is coated to coat it with a topcoat; and spraying a rinse solution including an acetate-based compound on the substrate coated with the topcoat to remove the topcoat.

The structural unit containing the hydroxy group and the fluorine may be represented by Chemical Formula 1.

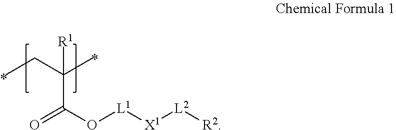

In Chemical Formula 1,

R¹ may be hydrogen or a substituted or unsubstituted C1 to C10 alkyl group,

R² may be hydrogen, a fluorine, a hydroxy group, or a substituted or unsubstituted C1 to C20 alkyl group,

L¹ and L² may be each independently a single bond, or a substituted or unsubstituted C1 to C10 alkylene group,

X¹ may be a single bond, —O—, —S—, —S(O)—, —S(O)₂—, —C(O)—, —(CO)O—, —O(CO), —O(CO)O—, or —NR′— (wherein, R′ may be hydrogen, deuterium, or a C1 to C10 alkyl group),

at least one selected from R², L¹, and L² may include a fluorine and a hydroxy group, and

*is a linking point.

For example, the structural unit containing the hydroxy group and the fluorine may be represented by Chemical Formula 2.

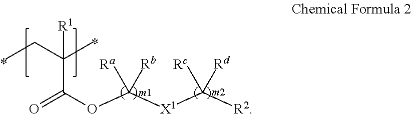

In Chemical Formula 2,

R¹ may be hydrogen or a substituted or unsubstituted C1 to C10 alkyl group,

R^{a}, R^{b}, R^{c}, R^{d}, and R² may be each independently hydrogen, a fluorine, a hydroxy group, or a substituted or unsubstituted C1 to C20 alkyl group,

m1 and m2 are each independently an integer from 1 to 10,

X¹ may be a single bond, —O—, —S—, —S(O)—, —S(O)₂—, —C(O)—, —(CO)O—, —O(CO), —O(CO)O—, or —NR′— (wherein, R′ may be hydrogen, deuterium, or a C1 to C10 alkyl group), and

R^{a}, R^{b}, R^{c}, R^{d}, and R² may together include a fluorine and a hydroxy group.

For example, the structural unit containing the hydroxy group and the fluorine may be selected from the compounds in Group I.

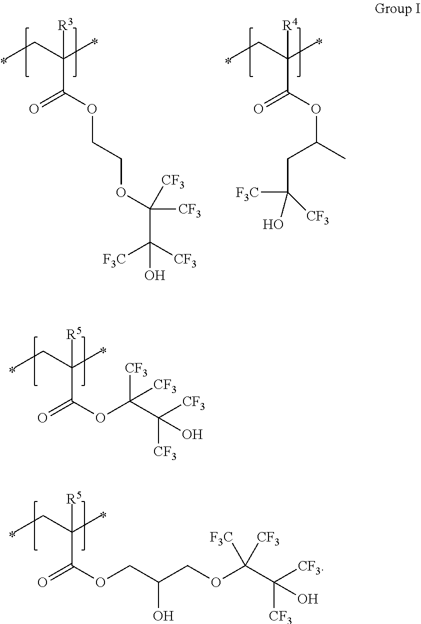

In Group I, R³ to R⁶ may be each independently hydrogen or a methyl group, and * is a linking point.

A weight average molecular weight of the acrylic polymer may be about 1,000 g/mol to about 50,000 g/mol.

The acid compound may be at least one selected from a sulfonic acid compound containing at least one fluorine, a sulfonimide compound containing at least one fluorine, and a carboxylic acid compound containing at least one fluorine.

The acid compound may be at least one of compounds represented by Chemical Formula 3 to Chemical Formula 6.

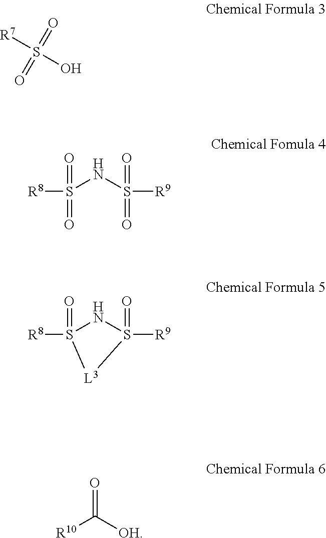

In Chemical Formula 3 to Chemical Formula 6,

R⁷ to R¹⁰ may be each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, and

L³ may be a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

The acid compound may be at least one of compounds of Group II.

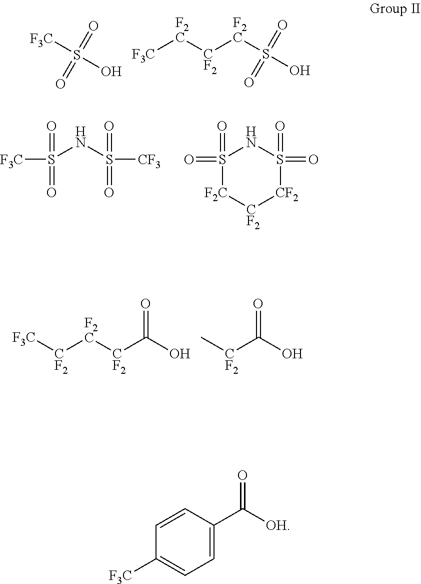

The acrylic polymer and the acid compound may be included in a weight ratio of about 3:1 to about 30:1.

A total weight of the acrylic polymer and the acid compound may be about 0.1 wt % to about 10 wt % based on the total weight of the organic topcoat composition.

The organic topcoat composition may include an ether-based solvent.

The acetate-based compound may be represented by Chemical Formula 7.

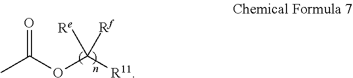

In Chemical Formula 7,

n is an integer from 1 to 10,

R^{e} and R^{f} may be each independently hydrogen, or a substituted or unsubstituted C1 to C10 alkyl group, and

R¹¹ may be a substituted or unsubstituted C1 to C20 alkyl group, or a substituted or unsubstituted C6 to C20 aryl group.

For example, in Chemical Formula 7, n may be an integer of 1 to 5, R^{e} and R^{f} may each independently be hydrogen, or a substituted or unsubstituted C1 to C6 alkyl group, and R¹¹ may be a substituted or unsubstituted C1 to C10 alkyl group.

For example, the acetate-based compound may be selected from compounds of Group III.

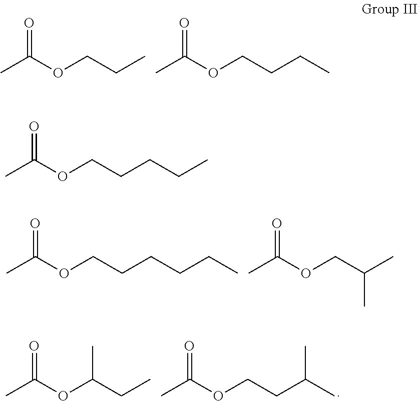

According to one or more embodiments, a semiconductor device includes a substrate on which a photoresist pattern manufactured according to the aforementioned method for forming photoresist patterns is formed.

The method for forming photoresist patterns may be capable of effectively (or suitably) removing the SLO defects without loss (or substantially without loss) of the photoresist fine pattern.

In addition, the method of the present embodiments is advantageous in terms of process economy by introducing a relatively simple post-treatment method without uses of expensive materials and complicated processes (e.g., process steps).

Accordingly, the method for forming photoresist patterns according to the present embodiments may be advantageously used for forming a fine pattern of a photoresist using a high energy light source such as EUV.

### BRIEF DESCRIPTION OF THE DRAWING

The drawing is a cross-sectional view illustrating acts of a method for forming photoresist patterns according to one or more embodiments of the present disclosure.

### DETAILED DESCRIPTION

Example embodiments of the present disclosure will hereinafter be described in more detail, and may be easily performed by a person skilled in the art. However, this disclosure may be embodied in many different forms and is not construed as limited to the example embodiments set forth herein.

In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, “substituted” refers to replacement of a hydrogen atom of a compound by a substituent selected from a halogen atom (F, Br, Cl, and/or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, “hetero” refers to a group or substituent including 1 to 10 heteroatoms selected from N, O, S, and P.

In addition, in the present specification, the acrylic polymer refers to an acrylic polymer and/or a methacrylic polymer.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is GPC LF-804 from Shodex, standard sample is polystyrene from Shodex).

In addition, unless otherwise defined in the specification, “*” indicates a linking point of a structural unit or a compound moiety to the main compound.

As used herein, singular forms such as “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of,” “one of,” and “selected from,” when preceding a list of elements, modify the entire list of elements and do not modify the individual elements of the list. As used herein, the term “and/or” includes any and all combinations of one or more of the associated listed items.

The term “may” will be understood to refer to “one or more embodiments,” some of which include the described element and some of which exclude that element and/or include an alternate element. Similarly, alternative language such as “or” refers to “one or more embodiments,” each including a corresponding listed item.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, a resist topcoat composition according to one or more embodiments is described.

The present disclosure relates to a resist topcoat composition capable of improving photoresist patterning by adding a simple process during the fine pattern forming process of photolithography using a short-wavelength light source such as an ArF excimer laser (wavelength: 193 nm) or high energy rays such as extreme ultraviolet (EUV; wavelength: 13.5 nm) to remove SLO defects remaining in the resist pattern, and a method for forming a photoresist pattern using such a topcoat.

A method for forming photoresist patterns according to one or more embodiments will be described with reference to the drawing.

A method for forming patterns according to one or more embodiments may include forming a photoresist pattern (e.g., a preliminary photoresist pattern) 102a on a substrate 100 (1), coating an organic topcoat composition including an acrylic polymer, the acrylic polymer including a structural unit containing a hydroxy group and a fluorine, and an acid compound on the preliminary photoresist pattern 102a, drying and heating the substrate 100 on which the organic topcoat composition is coated to coat it with (e.g., to form) a topcoat 30 (2), and spraying a rinse solution including an acetate-based compound on the substrate coated with the topcoat to remove the topcoat (3).

The forming of the preliminary photoresist pattern on the substrate (1) may include coating a semiconductor resist composition resist on the substrate 100 by spin coating, slit coating, and/or inkjet printing, forming a photoresist film 101 by drying and heating the coated semiconductor resist composition, and selectively exposing and developing the photoresist film 101 to dissolve and remove the photoresist layer corresponding to the exposed area to form a preliminary photoresist pattern 102a.

The forming of the preliminary photoresist pattern 102a may be performed by any suitable method, and details thereof will not be provided.

In the preliminary photoresist pattern 102a formed according to embodiments of the present disclosure, the bridge 10, connected to the adjacent pattern, and the scum 20, remaining in the gap between the patterns, may occur, and these defects may cause SLO defects in the thin film pattern to be formed later and may cause a decrease of yield.

In order to remove a bridge 10 and a scum 20 remaining after the formation of the preliminary photoresist pattern 102a, the method for forming photoresist patterns according to one or more embodiments may include coating an organic topcoat composition including an acrylic polymer, the acrylic polymer including a structural unit containing a hydroxy group and a fluorine, and an acid compound on the preliminary photoresist pattern 102a, drying and heating the substrate coated with the organic topcoat composition to form a topcoat 30 (process (2) in the drawing), and spraying a rinse solution including an acetate-based compound on the substrate coated with the topcoat 30 to remove the topcoat 30 (process (3) in the drawing).

The organic topcoat composition may include an acrylic polymer, and the acrylic polymer may include a structural unit containing a hydroxy group and the fluorine.

For example, the structural unit containing the hydroxy group and the fluorine may be represented by Chemical Formula 1:

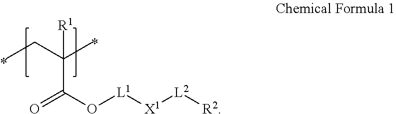

In Chemical Formula 1,

R¹ is hydrogen or a substituted or unsubstituted C1 to C10 alkyl group,

R² is hydrogen, a fluorine, a hydroxy group, or a substituted or unsubstituted C1 to C20 alkyl group,

L¹ and L² are each independently a single bond, or a substituted or unsubstituted C1 to C10 alkylene group,

X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R², L¹, and L² together include a fluorine and a hydroxy group, and

*is a linking point.

The description that R², L¹, and L² together include a fluorine and the hydroxy group may mean that:

R² is a C1 to C10 alkyl group substituted with at least one fluorine and at least one hydroxy group, or

at least one selected from L¹ and L² is a C1 to C10 alkylene group substituted with at least one fluorine and at least one hydroxy group, or

at least one selected from L¹ and L² is a C1 to C10 alkylene group substituted with at least one fluorine and the other is a C1 to C10 allylene group substituted with at least one hydroxy group, or

R² is a fluorine and at least one selected from L¹ and L² is a C1 to C10 alkylene group substituted with a hydroxy group, or

R² is a hydroxy group and at least one selected from L¹ and L² is a C1 to C10 alkylene group substituted with a fluorine, or

R² is a C1 to C10 alkyl group substituted with at least one fluorine and at least one hydroxy group, or

R² is a C1 to C10 alkyl group substituted with a C1 to C10 alkyl group substituted with at least one hydroxy group and at least one fluorine.

For example, the acrylic polymer may include a structural unit represented by Chemical Formula 2:

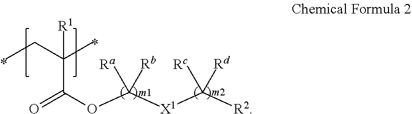

In Chemical Formula 2,

R¹ is hydrogen or a substituted or unsubstituted C1 to C10 alkyl group,

R^{a}, R^{b}, R^{c}, R^{d}, and R² are each independently hydrogen, a fluorine, a hydroxy group, or a substituted or unsubstituted C1 to C20 alkyl group,

m1 and m2 are each independently an integer from 1 to 10,

X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R^{a}, R^{b}, R^{c}, R^{d}, and R² include a fluorine and a hydroxy group, and

*is a linking point.

The statement that R^{a}, R^{b}, R^{c}, R^{d}, and R² together include a fluorine and a hydroxy group indicates that at least one fluorine and at least one hydroxy group are included within the combination of R^{a}, R^{b}, R^{c}, R^{d}, and R², for example:

at least one selected from R^{a}, R^{b}, R^{c}, R^{d}, and R² is a C1 to C10 alkyl group substituted with a fluorine and at least one of the remaining groups is a C1 to C10 alkyl group substituted with a hydroxy group, or

at least one selected from R^{a}, R^{b}, R^{c}, R^{d}, and R² is each independently a C1 to C10 alkyl group substituted with a hydroxy group and a fluorine, or

at least one selected from R^{a}, R^{b}, R^{c}, R^{d}, and R² is each independently a C1 to C10 alkyl group substituted with a C1 to C10 alkyl group substituted with a hydroxy group and a fluorine, or

at least one selected from R^{a}, R^{b}, R^{c}, R^{d}, and R² is a fluorine and at least one of the remaining groups is a hydroxy group, or

at least one selected from R^{a}, R^{b}, R^{c}, R^{d}, and R² is a fluorine and at least one of the remaining groups is a C1 to C10 alkyl group substituted with a hydroxy group, or

at least one selected from R^{a}, R^{b}, R^{c}, R^{d}, and R² is a hydroxy group and at least one of the remaining groups is a C1 to C10 alkyl group substituted with a fluorine, or

at least one selected from R^{a}, R^{b}, R^{c}, R^{d}, and R² is a C1 to C20 alkyl group substituted with a fluorine and at least one of the remaining groups is a C1 to C20 alkyl group substituted with a hydroxy group.

For example, R¹ may be hydrogen or a methyl group,

X¹ may be a single bond or —O—, and

R² may be a fluorine, a hydroxy group, a C1 to C10 alkyl group substituted with at least one fluorine, or a C1 to C10 alkyl group substituted with at least one hydroxy group.

For example, R^{c}, R^{d}, and R² of Chemical Formula 2 may include a fluorine and a hydroxy group.

For example, at least one selected from R^{c} and R^{d} in Chemical Formula 2 may be a fluorine or a C1 to C10 alkyl group substituted with at least one fluorine, and R² may be a hydroxy group or a C1 to C10 alkyl group substituted with at least one hydroxy group.

For example, at least one selected from R^{c} and R^{d} in Chemical Formula 2 may be a hydroxy group or a C1 to C10 alkyl group substituted with at least one hydroxy group, and R² may be a fluorine or a C1 to C10 alkyl group substituted with at least one fluorine.

For example, in Chemical Formula 2, R^{c} may be a hydroxy group or a C1 to C10 alkyl group substituted with at least one hydroxy group, R^{d} may be a fluorine or a C1 to C10 alkyl group substituted with at least one fluorine, and R² may be a hydroxy group, a fluorine, or a C1 to C10 alkyl group substituted with at least one fluorine or at least one hydroxy group.

For example, at least one selected from R^{c} and R^{d} of Chemical Formula 2 may be a fluorine or a C1 to C10 alkyl group substituted with at least one fluorine, R² may be a hydroxy group, or a C1 to C5 alkyl group substituted with a C1 to C5 alkyl group substituted with at least one hydroxy group and at least one fluorine.

For example, the structural unit containing the hydroxy group and the fluorine may be selected from Group I.

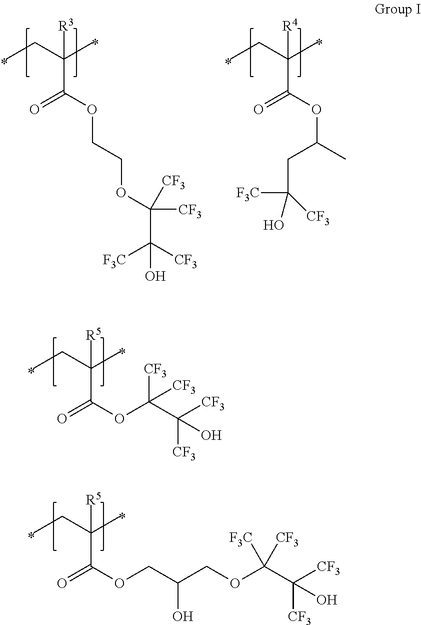

In Group I, R³ to R⁶ are each independently hydrogen or a methyl group, and * is a linking point.

Because the acrylic polymer includes the structural unit containing the hydroxy group and the fluorine at the same time (or concurrently), it has desired or excellent solubility in an organic solvent, may be uniformly (or substantially uniformly) coated on a pattern, and may minimize or reduce the influence on the photoresist.

The acrylic polymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example, about 4,000 g/mol to about 10,000 g/mol, but not limited thereto. When the weight average molecular weight of the acrylic polymer is within the above range, a carbon content and solubility in a solvent of the organic topcoat composition may be optimized or improved.

In one or more embodiments, the organic topcoat composition includes an acid compound, and the acid compound may include at least one selected from a sulfonic acid compound containing at least one fluorine, a sulfonimide compound containing at least one fluorine, and a carboxylic acid compound containing at least one fluorine.

For example, the acid compound may be a mixture including two types (e.g., two kinds) of compounds. As a mixture including two types (e.g., two kinds) of compounds, two types (e.g., two kinds) of compounds selected from a sulfonic acid compound containing at least one fluorine, and a sulfonimide compound containing at least one fluorine may be included in a weight ratio of about 1:0.1 to about 1:50. For example, the two types (e.g., two kinds) of the acid compounds may be included in a weight ratio of about 1:0.3 to about 1:40, for example about 1:0.3 to about 1:35, or about 1:1 to about 1:30.

As described above, when a mixture including two types (e.g., two kinds) of acid compounds is added, the defect portion of the resist may be selectively removed.

According to one or more embodiments, a high-resolution pattern may be obtained with a high yield.

For example, the acid compound may be at least one of compounds represented by Chemical Formula 3 to Chemical Formula 6:

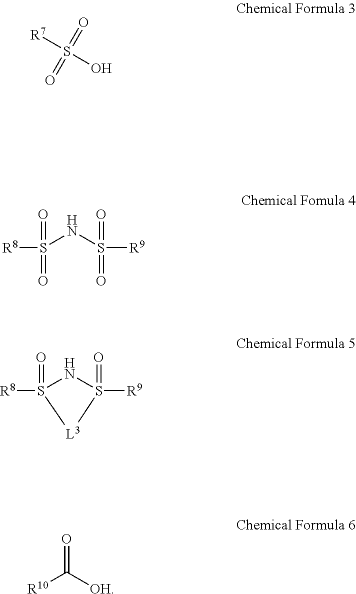

In Chemical Formula 3 to Chemical Formula 6,

R⁷ to R¹⁰ are each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, nd

L³ is a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

For example, R⁷ to R¹⁰ may each independently be a C1 to C10 alkyl group substituted with at least one fluorine, or a C6 to C20 aryl group substituted with at least one fluorine.

For example, the acid compound may be at least one of the compounds of Group II.

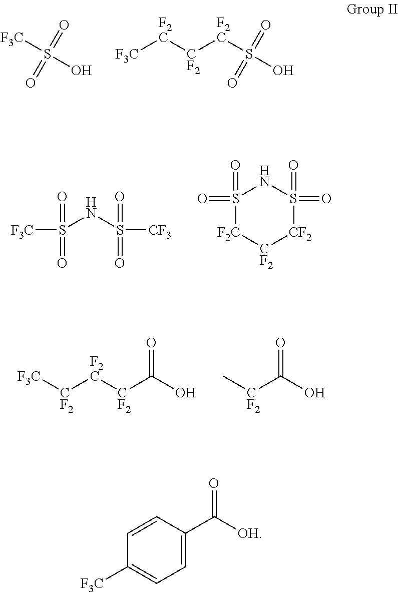

In one or more embodiments, the acrylic polymer and the acid compound may be included in a weight ratio of about 3:1 to about 30:1, for example, about 5:1 to about 25:1, or about 5:1 to about 20:1.

By including the acrylic polymer and the acid compound in the above weight ratio, an organic topcoat that is easy (or suitable) for SLO defect removal may be provided.

A total weight of the acrylic polymer and the acid compound may be about 0.1 wt % to about 10 wt % based on the total weight of the organic topcoat composition.

Within the above range, the organic topcoat may be easily (or suitably) removed.

In one or more embodiments, the organic topcoat composition may further include at least one other polymer selected from an epoxy-based resin, a novolac-based resin, a glycoluril-based resin, and a melamine-based resin, but is not limited thereto.

The organic topcoat composition may further include an additive including a surfactant, a thermal acid generator, a plasticizer, or a combination thereof.

The surfactant may be, for example, an alkylbenzenesulfonic acid salt, an alkylpyridinium salt, polyethylene glycol, a quaternary ammonium salt, and/or the like, but is not limited thereto.

The thermal acid generator may be, for example, an acid compound such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, benzoin tosylate, 2-nitrobenzyl tosylate, and/or other organic sulfonic acid alkyl ester(s), but is not limited thereto.

The additive may be included in an amount of about 0.001 to about 40 parts by weight based on 100 parts by weight of the organic topcoat composition. Within the above range, solubility may be improved without changing the optical properties of the organic topcoat composition.

In one or more embodiments, the organic topcoat composition may include an organic solvent having sufficient solubility and/or dispersibility with respect to the organic topcoat composition.

The organic solvent may include an ether-based compound, and for example, the ether-based compound may be represented by Chemical Formula 8:

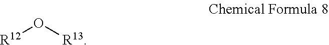

In Chemical Formula 8,

R¹² and R¹³ are each independently a substituted or unsubstituted C3 to C20 alkyl group.

For example, the ether-based compound may be selected from diisopropylether, dipropylether, diisoamylether, diamylether, dibutylether, diisobutylether, di-sec-butylether, dihexylether, bis(2-ethylhexyl)ether, didecylether, diundecylether, didodecylether, ditetradecylether, hexadecylether, butylmethylether, butylethylether, butylpropylether, tert-butylmethylether, tert-butylethylether, tert-butylpropylether, di-tert-butylether, cyclopentylmethylether, cyclohexylmethylether, cyclopentylethylether, cyclohexylethylether, cyclopentylpropylether, cyclopentyl-2-propylether, cyclohexylpropylether, cyclohexyl-2-propylether, cyclopentylbutylether, cyclopentyl-tert-butylether, cyclohexylbutylether, cyclohexyl-tert-butylether, 2-octanone, 4-heptanone, and a combination thereof.

The organic topcoat may be in a cured form, for example, by coating the organic topcoat composition on a photoresist pattern (e.g., on a preliminary photoresist pattern) and then drying and heating the same.

The heating of the substrate on which the organic topcoat composition is coated may be performed at a temperature of about 100° C. to about 500° C.

In the spraying of the rinse solution on the substrate coated with the topcoat to remove the topcoat, the rinse solution may include a solvent having low reactivity with the photoresist and high solubility for the topcoat, and for example, may include an acetate-based compound.

The acetate-based compound included in the rinse solution may be represented by Chemical Formula 7:

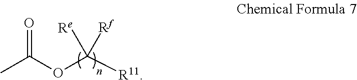

In Chemical Formula 7,

n is an integer from 1 to 10,

R^{e} and R^{f} are each independently hydrogen, or a substituted or unsubstituted C1 to C10 alkyl group, and

R¹¹ is a substituted or unsubstituted C1 to C20 alkyl group, or a substituted or unsubstituted C6 to C20 aryl group.

By including the acetate-based compound, it may have sufficient (or suitable) solubility and/or dispersibility in the organic topcoat composition while minimizing (or reducing) the effect on the photoresist.

For example, in Chemical Formula 7, n may be an integer of 1 to 5, R^{e} and R^{f} may each independently be hydrogen, or a substituted or unsubstituted C1 to C6 alkyl group, and R¹¹ may be a substituted or unsubstituted C1 to C10 alkyl group.

Examples of the acetate-based compound may include, but are not limited to, propyl acetate, n-butyl acetate, isobutyl acetate, sec-butyl acetate, n-amyl acetate, isoamyl acetate, and hexyl acetate.

In one or more embodiments, the acetate-based compound may be at least one selected from the compounds of Group III.

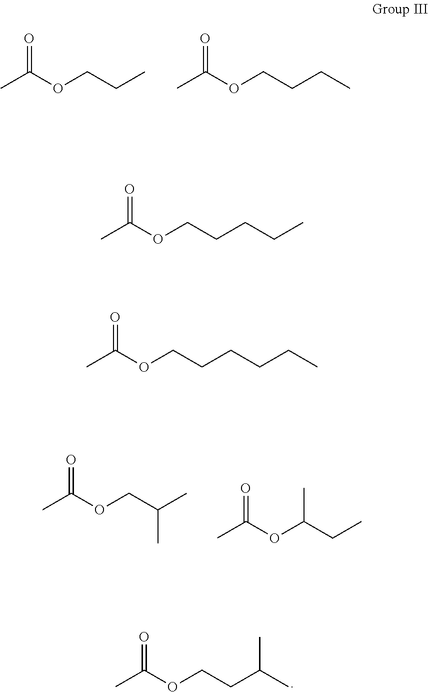

As such, in the photoresist pattern 102b formed after performing the coating of the topcoat (process (2) in the drawing) and removing of the topcoat (process (3) in the drawing), the bridge 10 and the scum 20 may be removed compared with the preliminary photoresist pattern 102a formed before performing the processes (2) and (3), so that the patterning of the photoresist may be improved.

The thin film pattern 103 may be finally formed through a process (4) of etching the exposed thin film of the substrate 100 by applying the photoresist pattern 102b as an etching mask, and in the thin film pattern 103 formed in this way, SLO defects may be effectively removed (or reduced) without loss of the fine pattern.

The method for forming photoresist patterns according to one or more embodiments is advantageous in realizing high resolution because the SLO defects are easily (or suitably) removed (or reduced).

Formation and removal of the organic topcoat may be performed by any suitable process, which is advantageous in terms of process economy, and the yield may be improved according to (e.g., due to) the removal of the SLO defects.

According to one or more other embodiments, a photoresist pattern manufactured according to the aforementioned method for forming photoresist patterns is provided.

The thin film may be etched, for example, by dry etching using an etching gas, and the etching gas may be, for example, CHF₃, CF₄, Cl₂, BCl₃, or a mixture thereof.

In the exposure process described above, the thin film pattern formed using the photoresist pattern 102b that is formed by the exposure process performed using the EUV light source may have a width corresponding to that of the photoresist pattern 102b. For example, the photoresist pattern 102b may have a width of about 5 nm to about 100 nm. For example, the thin film pattern 103 formed from the photoresist pattern 102b that is formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, similar to the photoresist pattern 102b, and in some embodiments, may be formed in a width of less than or equal to about 20 nm.

Hereinafter, embodiments of the present disclosure will be described in more detail through examples relating to the method of forming photoresist patterns.

However, the present disclosure is not technically limited by the following examples.

### SYNTHESIS EXAMPLES

### Synthesis of Acrylic Polymer

### Synthesis Example 1: Synthesis of Monomer

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (PH₃P) were mixed in 110 ml of diethylether under a nitrogen atmosphere and then, stirred. After the stirring for 30 minutes, the mixture was cooled down to 0° C., and another mixture of 14.52 g (71.84 mmol) of diisopropylazodicarboxylate (DIAD) and 35 ml of diethylether was slowly added thereto over 2 hours. Subsequently, the obtained mixture was stirred at room temperature for 24 hours and then, concentrated. The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

*¹H-NMR (Acetone-d6): δ1.90 (3H, t), 4.36 (4H, m), 5.63 (1H, t), 6.09 (1H, t), 8.34 (1H, s)

*¹⁹F-NMR (Acetone-d6): δ-70.12 (6F, m), −65.38 (6F, m)

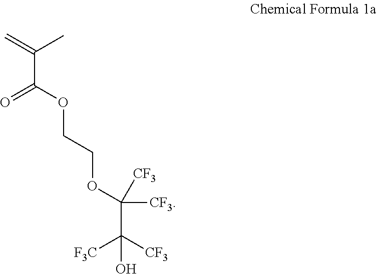 [SMILES: C=C(C)C(=O)OCCOC(C(F)(F)F)(C(F)(F)F)C(O)(C(F)(F)F)C(F)(F)F]

### Synthesis Example 2: Preparation of Copolymer P1

The compound represented by Chemical Formula 1a (37.5 g, 84.0 mmol) according to Synthesis Example 1, dimethyl 2,2′-azobis(2-methylpropionate) (2.5 g, 10.9 mmol, Wako Chemical, Inc.), and diisoamyl ether (DIAE, 60 g) as monomers were put in a 500 mL 2-necked round flask under a nitrogen atmosphere, and a condenser was connected thereto. After increasing the temperature to 110° C., the obtained mixture was reacted for 24 hours, and the reaction solution was cooled down to room temperature. The reaction solution was dropped into a 1 L wide-mouth bottle containing 225 g of heptane, while stirred, producing gum, and then, a supernatant was removed therefrom. After dissolving the remaining gum in 40 g of DIAE, 180 g of heptane was added thereto to form precipitates, and a supernatant was removed therefrom, and the process was repeated three times to remove monomolecules and oligomers.

As a result, 22.5 g of a polymer P1 including a structural unit represented by Chemical Formula 1 b (yield: 60% a weight average molecular weight: 4,500) was obtained.

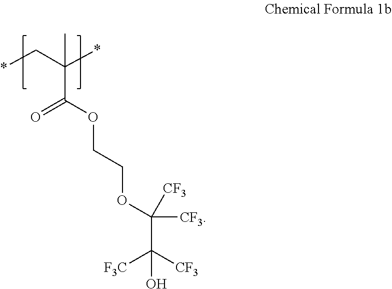

In Chemical Formula 1b, * is a linking point.

### Example 1

2 g (4.3 wt %) of the polymer P1 prepared in Synthesis Example 2, 0.04 g (0.09 wt %) of trifluoromethylsulfonic acid, and 0.10 (0.22 wt %) of bis(trifluoromethanesulfonyl)imide were dissolved in 44.4 g (95.4 wt %) of diisoamyl ether and then stirred at room temperature (23° C.) for 24 hours to prepare an organic topcoat composition.

Each organic topcoat composition was spin-on coated on a corresponding silicon substrate coated with a photoresist (e.g., a preliminary photoresist) and then, heat-treated on a hot plate at 110° C. for 1 minute, forming an about 50 nm-thick organic topcoat. Thereafter, propyl acetate represented by Chemical Formula R1 was applied as a rinse solution to rinse the topcoat, and heat treatment was performed at 110° C. for 1 minute on a hot plate to form a photoresist pattern.

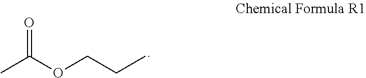

### Examples 2 to 7

Each photoresist pattern was formed in substantially the same manner as in Example 1, except that the rinse solution was changed as shown in Table 1.

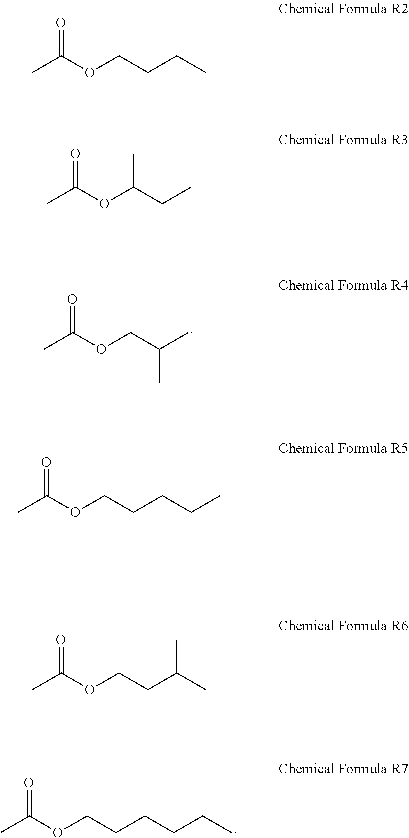

### Comparative Examples 1 and 2

Without coating the organic topcoat composition and forming the organic topcoat, the corresponding rinse solution as described in Table 1 was applied directly on the silicon substrate coated with the photoresist to rinse it, and heat treatment was performed at 110° C. for 1 minute on a hot plate to form a photoresist pattern.

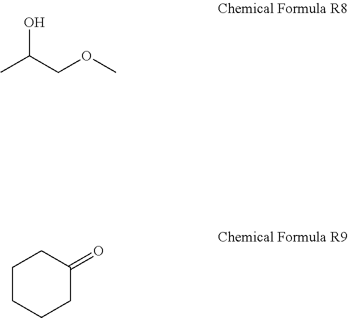

### Evaluation 1: Evaluation of Non-Pattern Wafer (NPW) Strip

Thickness changes of the photoresists prepared according to Examples 1 to 7 and Comparative Examples 1 and 2 were measured and NPW strips were calculated according to the following equation, and the results are shown in Table 1.

(NPW strip=PR thickness(nm)after rinsing−initialPR thickness(nm))

### Evaluation 2: Evaluation of SLO Defect

On a 12 inch silicon substrate, a lower SiON film, a spin-on carbon film, and a topcoat were sequentially formed. On the SiON film, a 1:1 line/space photoresist pattern with a pitch of 36 nm was formed by an EUV lithography method. The photoresist pattern was transferred into the lower SiON film through dry etching using plasma. Then, all defects including bridge defects between the line patterns were inspected with a defect analysis equipment using a deep ultraviolet (DUV) laser. The detected defects were classified by using scanning electron microscope (SEM), providing the number of the detected defects per unit area (ea/cm²).

Herein, when the number of SLO defects without using the organic topcoat compositions was converted into 100, ‘∘’ was given to a case in which the number of defects was less than or equal to 80%, and ‘X’ was given to a case in which the number of defects was greater than 80%.

TABLE 1

| | Acetate-based | NPW strip | |
|---|---|---|---|
| | compound | (nm) | SLO Defects |
| Example 1 | R1 | −3.5 | ◯ |
| Example 2 | R2 | −4.4 | ◯ |
| Example 3 | R3 | −3.8 | ◯ |
| Example 4 | R4 | −3.7 | ◯ |
| Example 5 | R5 | −4.1 | ◯ |
| Example 6 | R6 | −3.6 | ◯ |
| Example 7 | R7 | −3.5 | ◯ |
| Comparative | R8 | −28.1 | X |
| Example 1 | | | |
| Comparative | R9 | −27.5 | X |
| Example 2 | | | |

Referring to Table 1, the photoresist patterns prepared according to Examples 1 to 7, compared with the photoresist patterns prepared according to Comparative Examples 1 and 2, exhibited improved NPW strip (effective when between −5.0 nm to −2.5 nm) and SLO defect reduction.

Hereinbefore, certain embodiments of the present disclosure have been described and illustrated, however, it should be apparent to a person with ordinary skill in the art that the present disclosure is not limited to the embodiments as described herein, and may be variously suitably modified and transformed without departing from the spirit and scope of the present disclosure. Accordingly, the modified and/or transformed embodiments should not be understood separately from the technical ideas and aspects of the present disclosure, but rather the modified embodiments should be within the scope of the claims of the present disclosure and their equivalents.

Description of symbols

| | |
|---|---|
| 1: a process (e.g., a step) of forming a photoresist | |
| pattern on a substrate | |
| 2: a process (e.g., a step) of coating a topcoat on | |
| the photoresist pattern | |
| 3: a process (e.g., a step) of spraying a rinse | |
| solution on the substrate coated with the topcoat | |
| to remove the topcoat | |
| 4: a process (e.g., a step) of etching the exposed | |
| thin film by applying the photoresist pattern as an | |
| etching mask | |
| 10: bridge | 20: scum |
| 30: topcoat | |
| 100: substrate | 101: photoresist film |
| 102a: preliminary photoresist pattern formed before | |
| performing coating and removing the topcoat | |
| 102b: photoresist pattern formed after performing | |
| coating and removing the topcoat | |
| 103: thin film pattern | |

What is claimed is:

1. A method for forming photoresist patterns, the method comprising
forming a preliminary photoresist pattern on a substrate;
coating an organic topcoat composition comprising an acrylic polymer and an acid compound on the preliminary photoresist pattern, the acrylic polymer comprising a structural unit comprising a hydroxy group and a fluorine;
drying and heating the substrate on which the organic topcoat composition is coated to form a topcoat; and
spraying a rinse solution comprising an acetate-based compound on the substrate coated with the topcoat to remove the topcoat.

2. The method of claim 1, wherein the structural unit comprising the hydroxy group and the fluorine is represented by Chemical Formula 1: 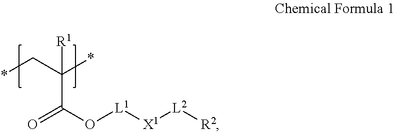
and
wherein, in Chemical Formula 1,
R¹ is hydrogen or a substituted or unsubstituted C1 to C10 alkyl group,
R² is hydrogen, a fluorine, a hydroxy group, or a substituted or unsubstituted C1 to C20 alkyl group,
L¹ and L² are each independently a single bond, or a substituted or unsubstituted C1 to C10 alkylene group,
X¹ is a single bond, —O—, —S—, —S(O)—, —S(O)₂—, —C(O)—, —(CO)O—, —O(CO), —O(CO)O— or —NR′— (wherein, R′ is hydrogen, deuterium, or a C1 to C10 alkyl group),
R², L¹, and L² together comprise a fluorine and a hydroxy group, and
*is a linking point.

3. The method of claim 1, wherein the structural unit comprising the hydroxy group and the fluorine is represented by Chemical Formula 2: 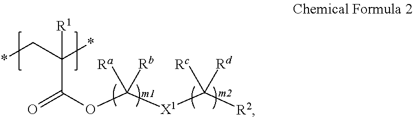
and
wherein, in Chemical Formula 2,
R¹ is hydrogen or a substituted or unsubstituted C1 to C10 alkyl group,
R^{a}, R^{b}, R^{c}, R^{d}, and R² are each independently hydrogen, a fluorine, a hydroxy group, or a substituted or unsubstituted C1 to C20 alkyl group,
m1 and m2 are each independently an integer from 1 to 10,
X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),
R^{a}, R^{b}, R^{c}, R^{d}, and R² together comprises a fluorine and a hydroxy group, and
*is a linking point.

4. The method of claim 1, wherein the structural unit comprising the hydroxy group and the fluorine is at least one selected from compounds of Group I: 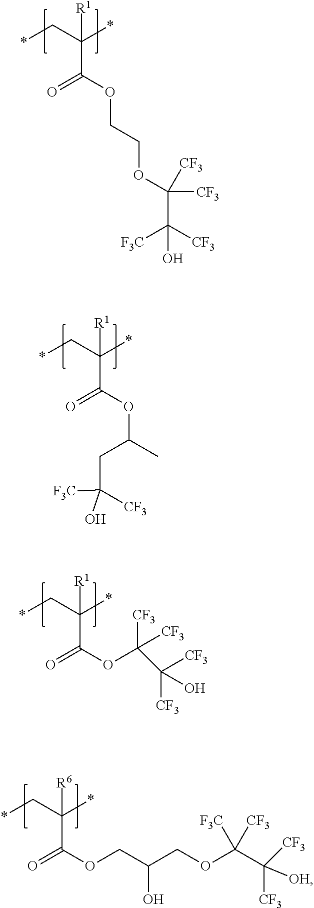
and
wherein, in Group I,
R³ to R⁶ are each independently hydrogen or a methyl group, and
*is a linking point.

5. The method of claim 1, wherein a weight average molecular weight of the acrylic polymer is about 1,000 g/mol to about 50,000 g/mol.

6. The method of claim 1, wherein the acid compound is at least one selected from a sulfonic acid compound comprising at least one fluorine, a sulfonimide compound comprising at least one fluorine, and a carboxylic acid compound comprising at least one fluorine.

7. The method of claim 1, wherein the acid compound is at least one selected from compounds represented by Chemical Formula 3 to Chemical Formula 6: 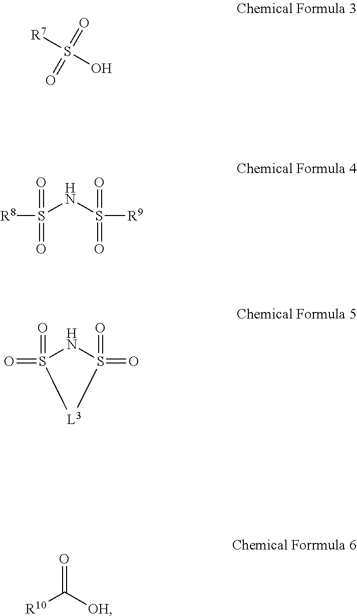
and
wherein in Chemical Formula 3 to Chemical Formula 6,
R⁷ to R¹⁰ are each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, and
L³ is a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

8. The method of claim 1, wherein the acid compound is at least one selected from compounds of Group II:

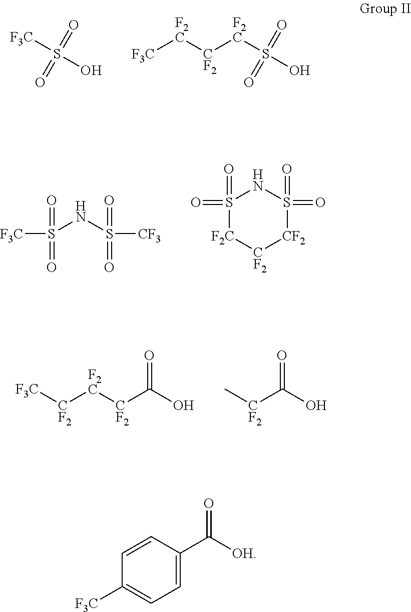

9. The method of claim 1, wherein the acrylic polymer and the acid compound are in a weight ratio of about 3:1 to about 30:1.

10. The method of claim 1, wherein a total weight of the acrylic polymer and the acid compound is about 0.1 wt % to about 10 wt % based on the total weight of the organic topcoat composition.

11. The method of claim 1, wherein the organic topcoat composition comprises an ether-based solvent.

12. The method of claim 1, wherein the acetate-based compound is represented by Chemical Formula 7: 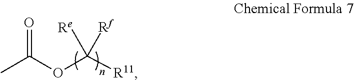
and
wherein in Chemical Formula 7,
n is an integer from 1 to 10,
R^{e} and R^{f} are each independently hydrogen, or a substituted or unsubstituted C1 to C10 alkyl group, and
R¹¹ is a substituted or unsubstituted C1 to C20 alkyl group, or a substituted or unsubstituted C6 to C20 aryl group.

13. The method of claim 12, wherein
in Chemical Formula 7, n is an integer of 1 to 5,
R^{e} and R^{f} are each independently hydrogen, or a substituted or unsubstituted C1 to C6 alkyl group, and
R¹¹ is a substituted or unsubstituted C1 to C10 alkyl group.

14. The method of claim 1, wherein the acetate-based compound is at least one selected from compounds of Group III:

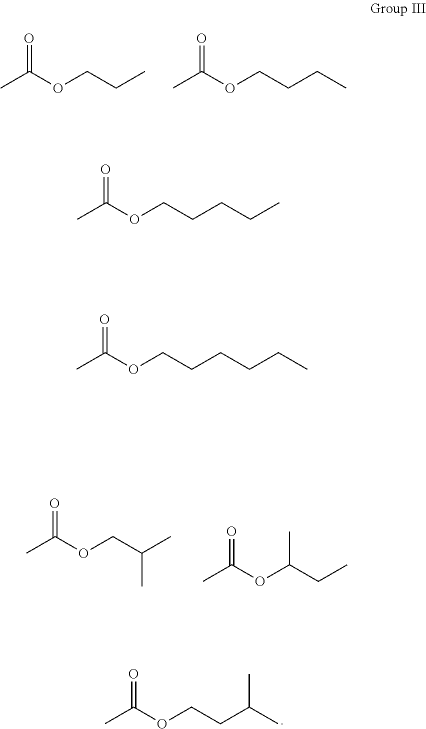

15. A semiconductor device comprising a substrate on which a photoresist pattern manufactured according to the method for forming photoresist patterns of claim 1 is formed.

16. A semiconductor device comprising a substrate with components formed with a photoresist pattern manufactured according to the method for forming photoresist patterns of claim 1.
